(19) United States
(12) Patent Application Publication
(10) Pub. No.: US 2007/0154650 A1
(43) Pub. Date: Jul. 5, 2007

(54) Method and apparatus for glow discharge plasma treatment of flexible material at atmospheric pressure

(75) Inventors: Mien-Win Wu, Longtan Township (TW); Cheng-Chang Hsieh, Chiayi City (TW); Chi-Fong Ai, Longtan Township (TW); Kuo-Chuan Cheng, Longtan Township (TW); Tien-Hsiang Hsuch, Sindlan City (TW)

Correspondence Address: TROXELL LAW OFFICE PLLC, SUITE 1404, 5205 LEESBURG PIKE, FALLS CHURCH, VA, 22041, US

(73) Assignee: Atomic Energy Council - Institute of Nuclear Energy Research

(21) Appl. No.: 11/320,609

(22) Filed: Dec. 30, 2005

(51) Int. Cl. B05D 3/00; H05H 1/24; C23C 16/00; B29C 71/04

(52) U.S. Cl. 427/532; 427/569; 118/718; 118/723 E

(57) ABSTRACT

Abstract of the disclosure The present invention provides a method and an apparatus for a glow discharge plasma surface treatment of flexible sheet materials under atmospheric pressure. The apparatus comprises electrodes, a single plasma-gas flow channel, uniform gas inlet-and-outlet devices, gas-seal devices for the horizontal movements of sheet materials and reel devices, so as to attain an uniform distribution of plasma gases in the gap between electrodes. As a result, not only a great amount of expensive plasma gas is saved, but also an uniform glow discharge plasma is generated at the lowest input power to obtain a good quality of uniform plasma treatment with continuous processing and high production.

### FIELD OF THE INVENTION

The present invention relates to a method and its associated apparatus for a surface treatment of flexible materials with an atmospheric pressure glow discharge plasma; more particularly, relates to an apparatus for a surface treatment of flexible sheet materials done by a glow discharge plasma under atmospheric pressure where a good quality of uniform treatment is obtained and a great amount of plasma gas is saved with continuous processing and high production.

### DESCRIPTION OF THE RELATED ARTS(S)

Since Kanazawa et al. first found in 1988 that a stable atmospheric pressure glow discharge plasma could be generated under certain circumstances, a lots of plasma experts around the world has been enthusiastically devoted their efforts to the development of the atmospheric pressure glow discharge plasma sources due to its great potential in industrial applications. Among them, the atmospheric plasma apparatus capable of continuous treatment meets the application requirements most for flexible materials, such as rolled fabric and polymer film. Although there have been three related prior arts of U.S. patent publications for similar applications, including: (a) U.S. Pat. No. 5,456,972, “Method and apparatus for glow discharge plasma treatment of polymer materials at atmospheric pressure”, proclaimed by Roth et al., in 1995; (b) U.S. Pat. No. 5,529,631, “Apparatus for the continuous surface treatment of sheet material”, proclaimed by Yoshikawa et al., in 1996,; and (c) No. 20030116281A1, “Atmospheric pressure plasma system”, proclaimed by Yoshikawa et al., in 2003, there has been a serious drawback in the design of these three patents. Please refer to FIG.6, which is a schematic view of the device for the prior arts. As shown in the figure, the pair of electrodes for the generation of the atmospheric pressure plasmas is embedded in a large plasma-gas chamber 11, so that in their apparatuses there are at least two plasma-gas flow channels 12 and 13, where the channel 12 is the gas flow space between two dielectric barrier plates of electrodes; and the channel 13 is the one outside the two dielectric barrier plates of electrodes. In order to reduce the operating cost by lowering the working voltage and power consumption in the surface treatment of flexible materials, such as a fabric or a polymer film, a small gap (<6 mm ) between the parallel dielectric barrier plates of electrodes has to be employed. Hence, the space between the dielectric barrier plates of electrodes has a much greater obstruction to the flow of plasma gas than that for the much wider space outside the dielectric barrier plates of electrodes. Thus, most of the plasma gas flows through the space outside the dielectric barrier plates and only very little amount of the gas passes through the narrow gap between dielectric barrier plates, resulting in a very low usage efficiency of the plasma gas. Owing to the expansive plasma gas used for the apparatus, its operating cost goes high, which obviously does not meet the requirements of industrial applications.

Firstly, the space uniformity of the glow discharge plasmas is essential for a good quality surface treatment. For the prior three patents of the atmospheric glow discharge plasma apparatuses, most of the input plasma gas predominantly fills up the space outside the dielectric barrier plates and only after the space is filled with the plasma gas, the plasma gas there starts to diffuse gradually into the narrow space between the dielectric barrier plates and dilutes the air presented there previously. Because the diffusion speed of the plasma gas is very low under an atmosphere pressure, the density of the plasma gas around the rim of the electrodes is always higher than that at the center of the electrodes so that the distribution of the plasma gas between the electrodes is not uniform and the density of the glow discharge plasmas generated is not uniform either.

Secondly, the conditions for the generation of a stable glow discharge plasma has been extensively investigated under atmospheric pressure According to the experiment done by N. Gherardi (published in the book by M. A. Lieberman etc., Principle of plasma discharges and material processing, John Willey & Sons. Inc., 1994), a slow flow of plasma gases between electrodes facilitates to the generation of a stable glow discharge plasmas. In addition, an efficient flow of the plasma gas can also lower the temperature of the plasma gas in the gap between the electrodes, which is good not only to the stability of the glow discharge plasmas, but also to the treatment of polymer materials which are not able to resist high-temperature environments. Regarding the design of the prior arts, most of the input plasma gas is filled up in the space outside of the gap of the electrode at the beginning stage, and then it gradually diffuses into the gap and dilutes the air there. After a discharge, the consumed plasma gas between electrodes is re-supplied mostly by the diffusion of the plasma gas outside of the electrodes through the rim of the electrodes. Therefore, the density of the plasma gas near the rim of the electrodes is always higher than that at the center. In another word, during all plasma-gas input phases, only a very small amount of plasma gas input into the plasma chamber enters directly into the gap between the electrodes and most of its plasma gases there is supplied by the diffusion of the plasma gases through the rim of the electrodes from outside of the electrodes. This leads to a too low gas flow rate to meet the requirements for the generation of a stable glow discharge plasmas.

In addition, in the device for the generation of glow discharge plasmas proclaimed in 2003 in the world patent publication No. WO003,086,031 A1, the design for an uniformly distributed gas inlet-and-outlet (I/O) device is still not included in spite of its much different design structure from the prior three patents. Hence, the plasma gas between the electrodes is not uniformly distributed and thus, the uniformity of the glow discharge plasma s generated from its apparatus is much in doubt.

As the above descriptions, although there are several apparatuses and methods in the prior arts can be applied for a surface treatment of the flexible sheet materials by using atmospheric glow discharge plasmas, there are still two serious drawbacks required for good solution, including the un-uniformity of the glow plasma for treating a flexible material of large area and the high consumption of plasma gases. Hence, the prior arts have not been adopted widely by the industrial enterprises. While, the greatest advantage of the present invention is that it can solve these two drawbacks completely.

### SUMMARY OF THE INVENTION

The main purpose of the present invention is, by integrating an uniform gas inlet-and-outlet (I/O) devices and a single plasma-gas flow channel to attain a good quality of surface treatment by using an atmospheric pressure glow discharge plasma and to save a great amount of expansive plasma gases, in addition to attain continuous processing and high production.

To achieve the above purpose, the present invention is an apparatus for a flexible sheet material surface treatment with a glow discharge plasma and a method thereof, where the apparatus comprises a pair of electrodes; a single plasma-gas flow channel consisting of a pair of dielectric barrier plates together with electrically insulated and air-sealed plates; a pair of uniform gas inlet-and-outlet devices with full gas tight seals; a pair of gas-seal devices for the horizontal movement of a flexible sheet material; and a pair of reel devices. Either a pulsed or a continuous AC (alternating current) power supply, is connected to the electrodes to effectively generate an uniform glow discharge plasma at the lowest input power for a surface treatment of the flexible sheet materials, comprising cleaning, disinfection serialization, activation, graft, polymerization, coarsens and coating. Accordingly, a novel apparatus for the uniform surface treatment of a flexible sheet material with an atmospheric pressure glow discharge plasma and a method there of are proposed.

### BRIEF DESCRIPTIONS OF THE DRAWINGS

The present invention will be better understood from the following detailed description of the preferred embodiment according to the present invention, taken in conjunction with the accompanying drawings, in which

FIG. 1 is a schematic view showing an apparatus according to a preferred embodiment of the present invention;

FIG. 2 is a schematic view showing a hermetic device for the horizontal movement of a flexible sheet material according to the preferred embodiment of the present invention;

FIG. 3 is across-sectional side view showing an uniform gas entrance and exit device according to the preferred embodiment of the present invention;

FIG. 4A and FIG. 4B are a side view and a top view showing an assembly of electrodes and dielectric barrier plates according to the preferred embodiment of the present invention;

FIG. 5 is a schematic view showing a cooling water device according to the preferred embodiment of the present invention; and

FIG. 6 is a schematic of an apparatus of a prior art.

### DESCRIPTION OF THE PREFERRED EMBODIMENT

The following description of the preferred embodiment is provided to understand the features and the structures of the present invention.

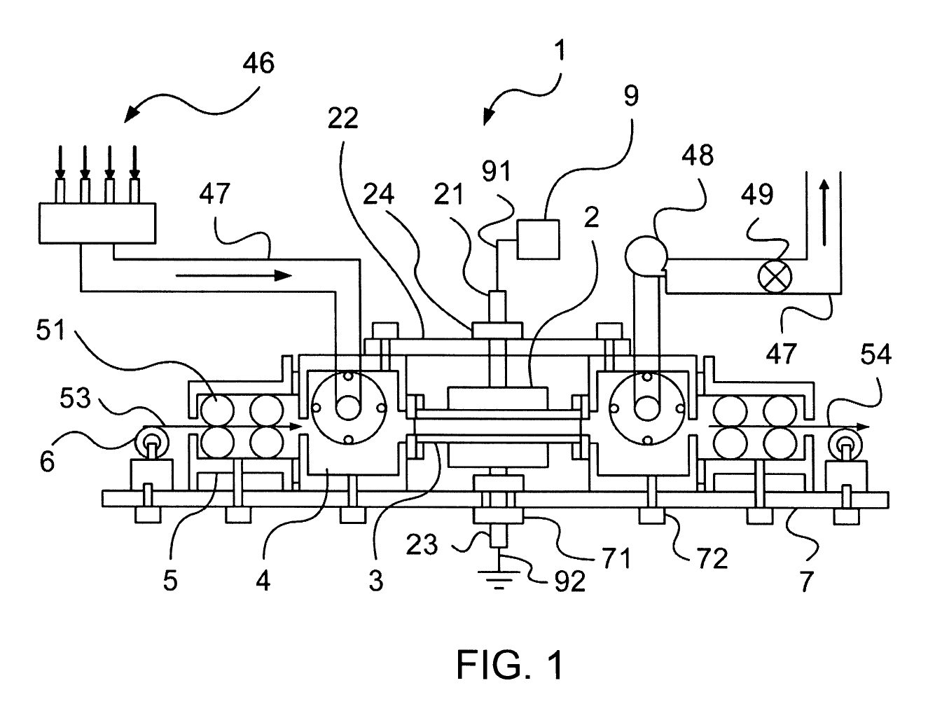

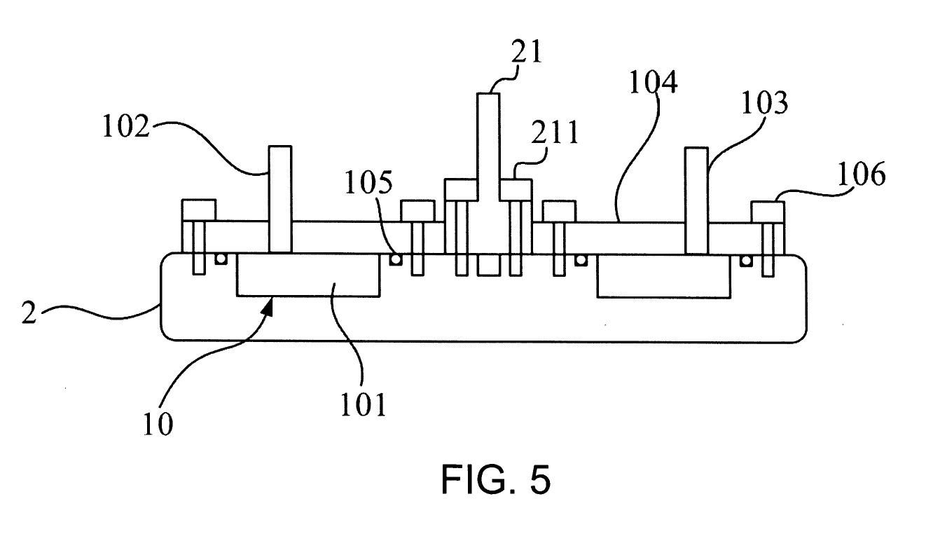

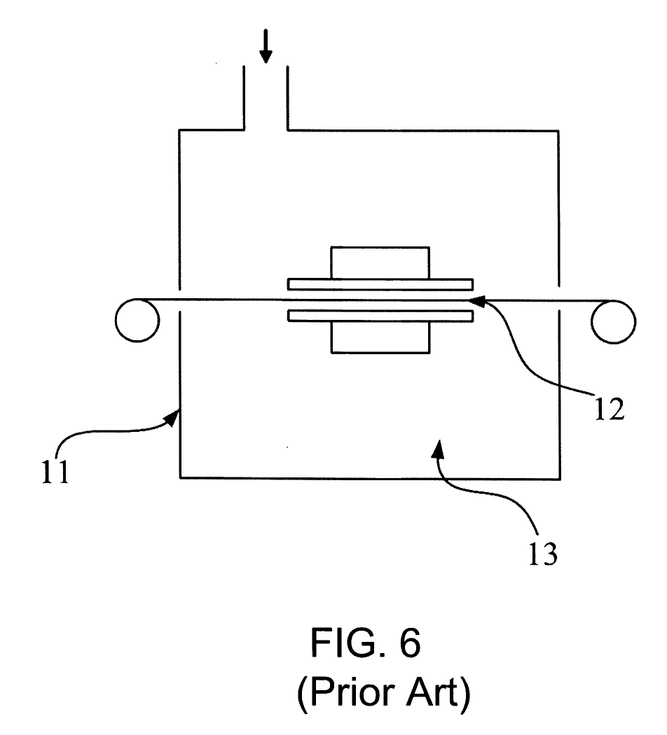

Please refer to FIG. 1, which is a schematic view showing an apparatus according to a preferred embodiment of the present invention. As shown in the figure, the present invention is an apparatus for a flexible sheet material surface treatment with glow discharge plasmas and a method thereof, where the apparatus 1 comprises a pair of electrodes 2; a pair of dielectric barrier plates 3; a pair of uniform gas entrance and exit devices 4; a pair of gas-seal devices 5 for the horizontal movement of a flexible material; and a pair of reel devices 6, and where, by u sing positioning nuts 71 and positioning screws 72, the apparatus 1 is fixed on a positioning plate 7. The electrode 2 is fixed to electrode positioning rod 21 through screws 211 (as shown in FIG. 5). The electrode positioning rod 21 is also used as a electrically conducting rod connected to a high-voltage power supply device 9 for obtaining the required high voltages. The high-voltage power supply device 9 provides either a pulsed or a continuous AC electric power with a voltage between 1 kV and 100 kV and a frequency between 1 kHz and 100 kHz. One of the electrode positioning rod 21 is connected to the high-voltage power supply device 9 through a high-voltage electrical wire 91; and another one of the electrode positioning rod 23 is grounded via a conducting wire 92. The electrode 2 is a rectangular metal plate, capable of performing a large-area and uniform surface treatment of a flexible material a long a horizontal movement. The flexible material can be a fabric or a polymer film. The electrode 2 can be made of aluminum or copper, which can be fabricated easily and have a good thermal conductivity. The gap between the electrodes 2 can be adjusted by using the electrode positioning rod 21, an electrode-gap adjusting base 22 and an electrode-gap ad justing nut 24. The thickness of the dielectric barrier plate 3 is preferred to be not greater than 2 mm, which is made of an electrically insulated material, which can be a glass, a plastic or a ceramic. The gap between the electrodes 2 is between 2 mm and 20 mm, which is preferably about 2 mm thicker than the thickness of the treated sheet material to avoid too much obstruction to the plasma gas flow.

A method for the apparatus 1 uses a glow plasma obtained within the apparatus 1 for a surface treatment of a flexible sheet material, where the method comprises a plasma treatment process for cleaning, disinfection, serialization, activation, graft, polymerization, coarsening and coating.

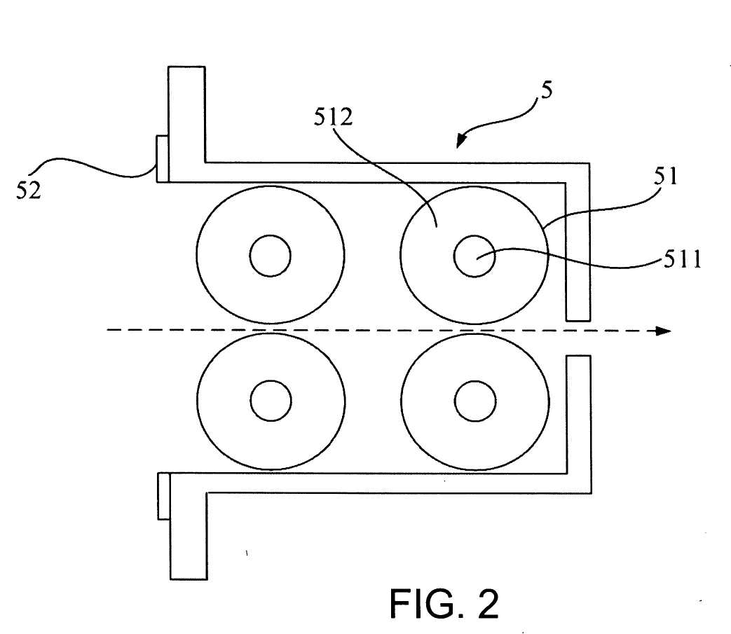

Please refer to FIG. 2, which is a schematic showing a gas-seal device for a horizontal movement of a flexible material according to the preferred embodiment of the present invention. As shown in the figure, the gas-seal device 5 comprises the structure of dual sets of cylinders 51. The gas-seal tightness of the gas-seal device 5 can be ad justed according to the material of the cylinder 5, the air tightness between the cylinders 5 and the flexible sheet material treated, and the moving speed of the flexible material. A turning shaft 511, made of metals or ceramics, is at the center of the cylinder 51 surrounded by a second rubber gasket 512. The gas-seal device 5 is connected to an uniform gas inlet-and-outlet device 4 (not shown in the figure) with a third rubber gasket 52 to increase the gas-tight seal between the gas-seal device 5 and the uniform gas inlet-and-outlet device 4. The rubber gaskets 512 and 52 are made of electrically insulated materials, which can be a soft plastic. Please further refer to FIG. 1. By that the air tightness of the gas-seal device 5 is further adjusted to obtain a better gas seal at the entrance 53 for the treating flexible materials than the gas-seal at the exit 54. This also facilitates the flow of the plasma gases in the gap of electrodes along a single direction. Another side of the gas-seal device 5 is connected to a reel device 2 to attain continuous processing and high production.

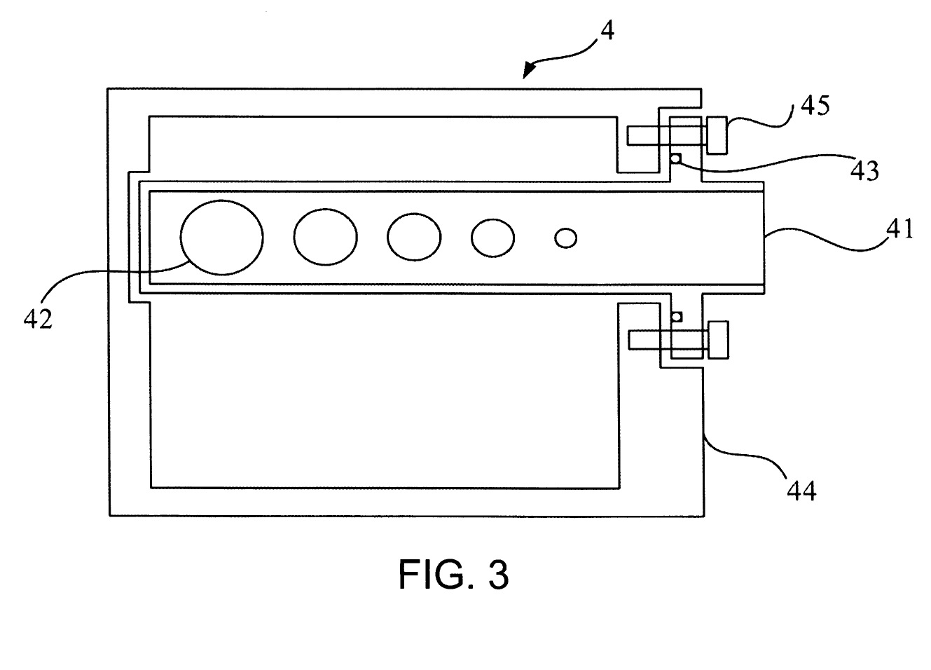

Please refer to FIG. 3, which is a cross-sectional side view showing an uniform gas inlet-and-outlet (I/O) device 4 according to a preferred embodiment of the present invention. As shown in the figure, the uniform gas I/O device 4 comprises a gas inlet-and-outlet (I/O) pipe 41 and a position-fixing base 44. The gas inlet-and-outlet (I/O) pipe 41 comprises at least two gas inlet-and-outlet (I/O) holes 42. The diameter of the gas I/O holes 42 is a directly proportional to the distance to the mouth of the gas I/O pipe 41. That is to say, the farther the gas I/O hole 42 is located from the mouth of the gas I/O pipe 41, the bigger the diameter of the gas I/O holes; on the contrary, the nearer the gas I/O hole 42 is located from the mouth of the gas I/O pipe 41, the smaller the diameter of the gas I/O holes; So, the smaller hole 42 located nearer from the mouth of the uniform gas I/O pipe 41 suffers for a greater obstruction to gas flow, while the bigger hole 42 located farther away from the mouth of the uniform gas I/O pipe 41 suffers for a lower obstruction to gas flow. As a result, the gas flow rate of the plasma gas for each hole 42 into the single plasma-gas flow channel is approximately the same. The uniform gas I/O pipe 41 is fixed to the positioning base 44 with an O-ring seal and a set of positioning screws so that a full gas tight seal is obtained. The plasma gas can be helium, argon or a mixture of helium, or argon, oxygen, nitrogen, O₂, air, NH₃, CF₄, C₃F₆, C₄F₈, and gaseous monomers in various proportion. Please further refer to FIG. 1, the plasma gas flow rate for each gas is controlled respectively at the inlet 46 and a mixture of plasma gases is guided through a flexible gas pipe 47 f or in put (output) to (out of) the uniform gas I/O pipe and the gap of electrodes, where an exhaust blower 48 or an air exhaust valve 49 can be used according to the activity of the plasma gas used for each application.

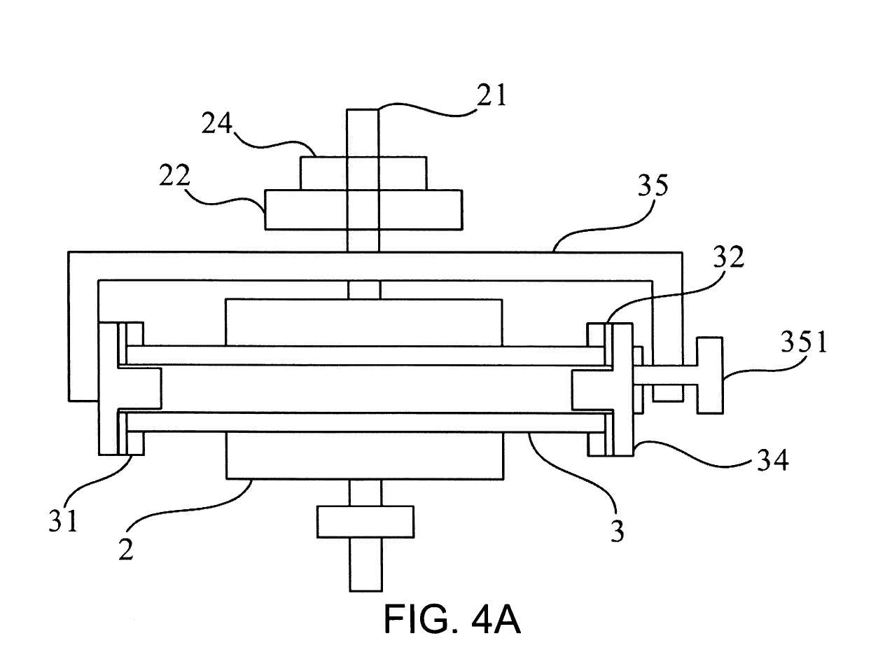

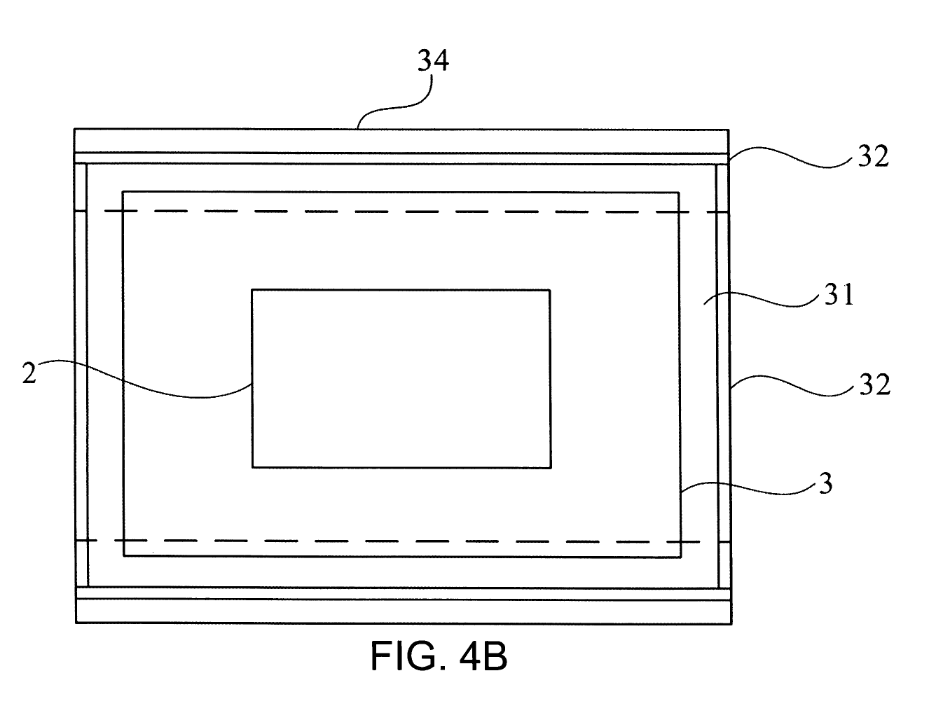

Please refer to FIG. 4A and FIG. 4B, which is respectively a side view and a top view showing an assembly of electrodes and dielectric barrier plates according to the preferred embodiment of the present invention. As shown in the figures, two electrodes 2 are ad he red to two dielectric barrier plates 3 with a thermally conductive and electrically insulating glue; and at the periphery of each dielectric barrier plate 3 is ad he red with a rectangular gas-seal insulated dam 31. Each of the surfaces, where the dielectric barrier plate 3 is connected with an uniform gas I/O device 4 (not shown in the figures), comprises a first rubber gasket 32 to improve its air tightness. Each of the surfaces, where the dielectric barrier plate 3 is not connected with the uniform gas I/O device 4, comprises a first rubber washer 32 and a gas-seal insulated plate 34 to obtain good air tightness; and further comprises an n-shaped gas-seal adjusting base 35 having a knob 351 for ad justing the tightness of the gas-seal insulated plate 34 for a better air-tightness.

Please refer to FIG. 5, which is a schematic view showing a cooling water device according to the preferred embodiment of the present invention. As shown in the figure, a cooling water device 10 is set on an electrode 2, comprising a cooling-water reservoirs 101, a cooling-water inlet pipe 102, a cooling-water outlet pipe 103, a cooling-water sealing plate 104, a pair of O-ring seals 105 and a plurality of positioning screws 106. The cooling water device 10 provides a cooling water of room temperature to cool down the temperature of the plasma gas, and to prevent the undesirable change in the characteristics of plasma discharge due to water condensation on the dielectric barrier plates of electrodes.

To sum up, the present inventions an apparatus for a flexible sheet material surface treatment with a glow plasma and a method thereof, where a surface treatment is done by an uniform glow discharge plasma so that a good quality of treatment is obtained and a great amount of plasma gas used is saved for continuous processing and high production.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

What is claimed is:

1. An apparatus for a flexible sheet material surface treatment with a glow discharge plasma, comprising:
(a) a pair of electrodes;
(b) a pair of connecting rods for high-voltage electric power, said connecting rod comprising a positioning rod and an adjusting nut, said positioning rod being a metal screw, said connecting rod fixing said electrode, said connecting rod adjusting a gap between said electrodes;
(c) a power supply device providing high-voltage electric power for said electrode through said connecting rod;
(d) a pair of dielectric barrier plates, said dielectric barrier plate fixed to said electrode with a silica gel, said dielectric barrier plate comprising an air-seal insulated plate and a rubber gasket at each rim of said dielectric barrier plate;
(e) a pair of uniform gas I/O (inlet/outlet) devices, said uniform gas I/O device comprising a uniform gas I/O pipe and a positioning base;
(f) a pair of gas-seal devices moving a flexible sheet material horizontally, said gas-seal device comprising at least one pair of cylinders;
(g) a pair of reel devices, said reel device delivering said flexible sheet material; and
(h) a positioning plate positioning and fixing said reel devices, said gas-seal devices, said uniform gas I/O devices and said electrodes by using positioning screws.

2. The apparatus according to claim 1, wherein said positioning screw further comprises a positioning nut.

3. The apparatus according to claim 1, wherein said electrode is made of a material selected from a group consisting of aluminum and copper.

4. The apparatus according to claim 1, wherein one of said connecting rod is connected to said high-voltage power supply device and another one of said connecting rod is grounded.

5. The apparatus according to claim 1, wherein said flexible material is a material selected from a group consisting of a fabric and a polymer film.

6. The apparatus according to claim 1 wherein said electrode further comprises a cooling water device.

7. The apparatus according to claim 1, wherein said dielectric barrier plate comprises a thickness not greater than 2 mm.

8. The apparatus according to claim 1 wherein said dielectric barrier plate and said gas-seal insulated plate are made of a material selected from a group consisting of a glass, a plastic and a ceramic.

9. The apparatus according to claim 1, wherein said rubber gasket is made of an electrically insulated material and said insulated material is a soft plastic.

10. The apparatus according to claim 1, wherein said gas-seal device comprises an element selected from a group consisting of a single pair of cylinders and dual pair of cylinders.

11. The apparatus according to claim 1, wherein said uniform gas I/O pipe comprises at lease two gas I/O holes.

12. The apparatus according to claim 1, wherein a plasma gas flows in from said uniform gas I/O pipe.

13. The apparatus according to claim 1 wherein said gap between said electrodes is adjusted to be in a range between 2 mm and 20 mm.

14. The apparatus according to claim 1 wherein said high-voltage power supply device is a power resource providing an electric power selected from a group consisting of an impulsive electric power and a continuous AC (alternating current) electric power.

15. The apparatus according to claim 1, wherein said power supply device comprises a voltage in a range between 1 kV and 100 kV.

16. The apparatus according to claim 1, wherein said power supply device comprises a frequency in a range between 1 kHz and 100 kHz.

17. The apparatus according to claim 10,
wherein said cylinder comprises a turning shaft and a rubber washer; and
wherein said turning shaft is made of a material selected from a group consisting of a metal and a ceramic.

18. The apparatus according to claim 11, wherein the diameter of the said gas I/O holes is directly proportional to the distance between said gas I/O hole and a mouth of said uniform gas I/O pipe.

19. The apparatus according to claim 1,
wherein said plasma gas is selected from a group consisting of helium, argon and a mixture of helium, argon and said member of gases; and
wherein said member of gases is selected from a group consisting of oxygen, nitrogen CO₂, air, NH₃, CF₄, C₃F₆, C₄F₈ and various gaseous monomers.

20. A method for the apparatus according to claim 1,
comprising a process of a cleaning, a disinfection, a serialization, an activation, a graft, a polymerization, a coarsening and a coating,
wherein said method utilizes said apparatus for a surface treatment of said flexible sheet material by using an atmospheric pressure glow discharge plasma obtained in said apparatus.
